(19) United States
(12) Patent Application Publication
(10) Pub. No.: US 2003/0071354 A1
(43) Pub. Date: Apr. 17, 2003

(54) Wafer level chip scale package and method of fabricating the same

(76) Inventors: Chin-Ying Tsai, Kaohsiung (TW); Ming-Chung Sung, Taichung (TW); Yun-Shien Yeh, Hsinchu Hsien (TW); Masayuki Ohi, Hsinchu (TW)

Correspondence Address: J.C. Patents, Inc., Suite 250, 4 Venture, Irvine, CA, 92618, US

(21) Appl. No.: 10/015,471

(22) Filed: Dec. 12, 2001

(30) Foreign Application Priority Data
Oct. 17, 2001 (TW) 90125638

(51) Int. Cl. H01L 23/48; H01L 29/40

(52) U.S. Cl. 257/738; 257/737; 257/778

(57) ABSTRACT

A wafer level chip scale package, having a chip, at least one dielectric layer, a stress buffer layer, multiple first solder balls and multiple second solder balls. By using an upper dielectric layer to cover a lower dielectric layer, the peeling effect between the dielectric layers is mitigated. Further, by forming the stress buffer layer and the chip with a stair-like structure, the peeling effect of the stress buffer layer is also mitigated, while the probability of moisture penetration into the package is minimized. A method for fabricating the above wafer level chip scale package is also introduced.

### CROSS-REFERENCE TO RELATED APPLICATION

This application claims the priority benefit of Taiwan application serial no. 90125638, filed Oct. 17, 2001.

### BACKGROUND OF THE INVENTION

1. Field of the Invention

The invention in general relates to a wafer level chip scale package (WLCSP), and more particularly, to a structure and a method of mitigating the peeling effect between dielectric layers formed on a chip of a wafer level chip scale package.

2. Description of the Related Art

In accordance with the highly advanced telecommunication in our modern society, the market of multi-medium application is rapidly expanding. The package technique for integrated circuits has to be developed in response to the influence of electronic equipment being digitized, network applicable, locally connectable, and humanized for the electronic equipment. To achieve the above objectives, high processing speed, multi-functional, integratable, small volume, light weight, and low cost are all required. Consequently, the integrated circuit package technique is developed towards the directions of being micro-miniaturized and high density. The typical chip scale package has a side length of less than 1.2 times the side length of the inside packaged chip or the chip area/package area is larger than 80% of the package. However, the chip scale package can still serve the functions even within a very small area and is able to employ standard surface mount technology (SMT) and equipment; the chip scale package has been widely adapted in industry.

FIG. 1 to FIG. 7 show the fabrication process of a conventional wafer level chip scale package. In FIG. 1, a wafer 100 is provided. A first dielectric layer 102 is formed on the wafer 100. A second dielectric layer 104 is formed on the first dielectric layer 102. A patterned conductive line is formed between the first dielectric layer 102 and the second dielectric layer 104 such that the pad positions on each chip of the wafer 100 can be re-distributed.

In FIG. 2, a first ball placement process is performed. The first solder balls 106 are formed on each under-ball metallurgy (UBM) on the second dielectric layer 104. The first solder balls 106 are allocated on the UBM that have been redistributed. Before the first ball placement process, a flux or other solder paste can be coated on the UBM to reinforce the adhesion between the first solder balls 106 and the corresponding UBM.

In FIG. 3, a stress buffer layer 108 is formed on the wafer 100. The stress buffer layer 108 encapsulates the first solder balls 106 and has a promising stress buffering function so that the reliability of the joint between the first solder balls and the carrier is improved.

In FIG. 4, a grinding step is performed to both the stress buffer layer 108 and the first solder balls 106.. The grinding step is stopped until the stress buffer layer 108 reaches an appropriate thickness. After the grinding step, the first solder balls 106 are been ground to an appropriate thickness so that a surface portion of the first solder balls 106 and a top surface of the stress buffer layer 108 are both exposed.

In FIG. 5, a second ball placement process is performed. The second solder balls 10 are allocated on the exposed first solder balls 110. Before the second ball placement process, a flux or other solder paste may be coated on the exposed surface portion of the first solder balls 106 to improve the adhesion between the first and second solder balls 106 and 110.

In FIG. 6, a solder back step is performed after allocating the second solder balls 110 on the first solder balls 106. Due to material fusion of the first and second solder balls 106 and 110, the bottom of the second solder balls 110 are mounted to the exposed part of the first solder balls 106.

FIG. 7 shows the occurrence of the peeling problem between the dielectric layers of a conventional wafer level chip scale package. In the conventional wafer level chip scale package, the difference in coefficient of thermal expansion (CTE) or the poor adhesion of different dielectric layers causes the peeling problem to occur between the dielectric layers, affecting the yield and reliability of the device.

Therefore, the peeling problem that affects the package yield and reliability is caused by the difference in coefficient of thermal expansion or poor adhesion of different dielectric layers in the conventional wafer level chip scale package.

In addition, as moisture may easily penetrate through the boundary into the package between the dielectric layer and the wafer, therefore the yield and reliability are further affected.

### SUMMARY OF THE INVENTION

The present invention provides a structure and a fabrication method of preventing the peeling problem caused by the difference in coefficient of the thermal expansion or the poor adhesion of different dielectric layers of a wafer level chip scale package.

In the present invention, a wafer level chip scale package including a chip, at least one dielectric layer, a stress buffer layer, multiple first solder balls, and multiple second solder balls is formed. The chip has an active area thereon. Multiple pads and a protective layer that protects the pads with the pads exposed are formed on the active area. The chip has a peripheral thickness smaller than that of the active area. The thickness difference between the peripheral area and the active area of the chip is about ⅓ to ½ of the thickness of the wafer.

A first dielectric layer is formed on the active area, while a second dielectric layer is formed on the first dielectric layer, which is thus covered thereby. A pattern conductive line is formed between the first and second dielectric layers as a redistribution layer of the pads on the chip. Multiple under-ball metallurgies are formed on the second dielectric layer and are electrically connected to the pads on the chip via the redistribution layer. The present invention provides a structure of preventing the peeling problem between two dielectric layers by encapsulating the first dielectric layer with the second dielectric layer.

The first solder balls are allocated on the under-ball metallurgies to be connected thereto. After being ground, the height of the first solder balls is about ¼ to ½ of the height of that before being ground.

The stress buffer layer is formed on the chip and is arranged in such a way that the stress buffer layer covers both the active area and the peripheral area of the chip. Further, the stress buffer layer also covers the first solder balls and leaves only a surface portion of the first solder balls to be exposed. The thickness difference between the peripheral area and the active area of the chip allows the side areas of the chip to be completely covered by the stress buffer layer. Consequently, the peeling problem is effectively prevented, and the chances of occurring the moisture penetration is greatly reduced.

The second solder balls are formed on the first solder balls and connected to the exposed parts thereof. A total height of the first solders after being ground plus a height of the second solder balls is about 300 microns to 700 microns.

The present invention further provides a fabrication method of a wafer level chip scale package. A wafer with multiple chips is provided. Each chip has an active area thereon. A plurality of pads and a passivation layer are formed on the active area of every chip. The passivation layer is used to protect the surface of the chip and allows the pads to be exposed. A first dielectric layer and a second dielectric layer are formed on the active area sequentially. The second dielectric layer is formed on the first dielectric layer and encapsulates the first dielectric layer. In addition, a patterned trace which is formed between the first dielectric layer and the second dielectric layer is used as a redistribution layer for the chip. The structure of using the second dielectric layer to encapsulate the first dielectric layer the above first and second dielectric layers improves the bonding between the layers and prevents the peeling problem to occur due to the different coefficient of the thermal expansion or the poor adhesion.

Multiple first solder balls are formed on the chip, followed by a solder back process. A pre-cut step is performed to form multiple trenches between the chips. A stress buffer layer is formed over the wafer. The trenches are filled with the stress buffer layer, while the first solder balls are covered therewith. The stress buffer is then ground to expose the first solder balls. Multiple second solder balls are then formed on the exposed first solder balls, followed by a solder back step. The second solder balls are thus fixed on the exposed first solder balls. A singulating process is then performed to wafer so that the chips are separated.

In the present invention, the cutting tool used in the pre-cut step has a blade wider than that used in the singulating step for separating the chips. The depth of the trenches formed in the pre-cut step is about ½ to ⅓ of the thickness of the wafer. After the singulation, the junction between the chip peripheral and the stress buffer layer effectively prevents the stress buffer from peeling off so that the probability of occurring the moisture penetration is reduced.

In addition, the height of the first solder balls after being ground is about ¼ to ½ of that before being ground.

Both the foregoing general description and the following detailed description are exemplary and explanatory only and are not restrictive of the invention, as claimed.

### BRIEF DESCRIPTION OF THE DRAWINGS

FIGS. 1 to 6 show the fabrication process for a conventional wafer level chip scale package;

FIG. 7 shows the peeling effect of the dielectric layer in a conventional wafer level chip scale package;

FIG. 8 to FIG. 15 show a wafer level chip scale package in one preferred embodiment of the present invention; and

FIG. 16 shows a redistribution layer between a first dielectric layer and a second dielectric layer of a wafer level chip scale package in one preferred embodiment of the present invention.

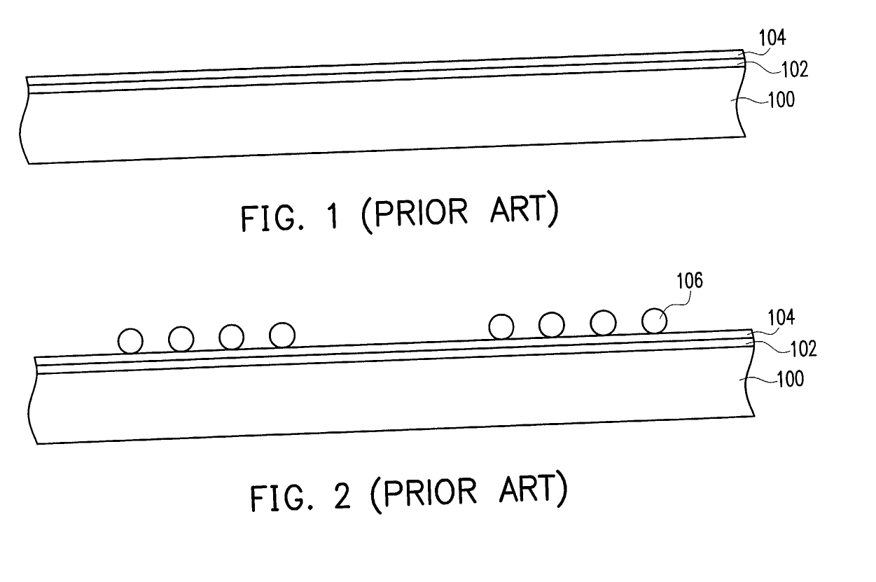

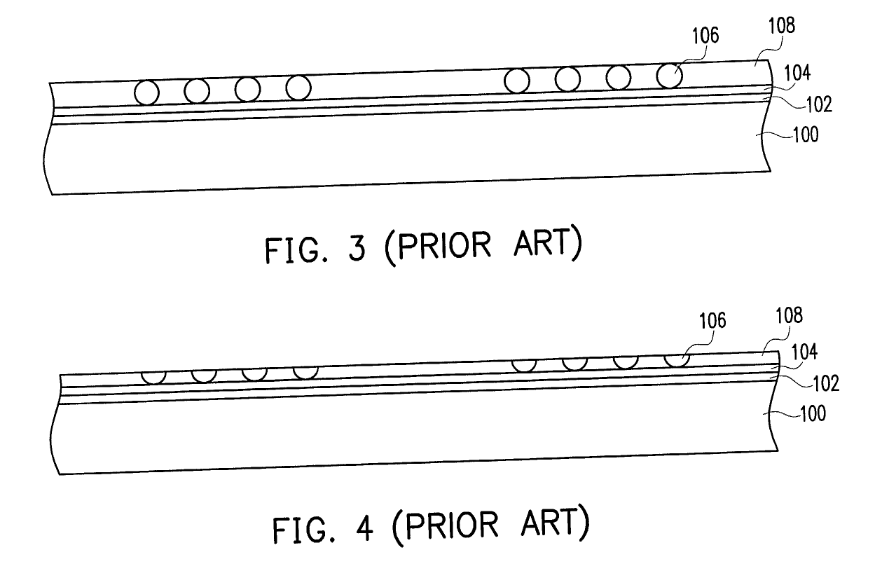

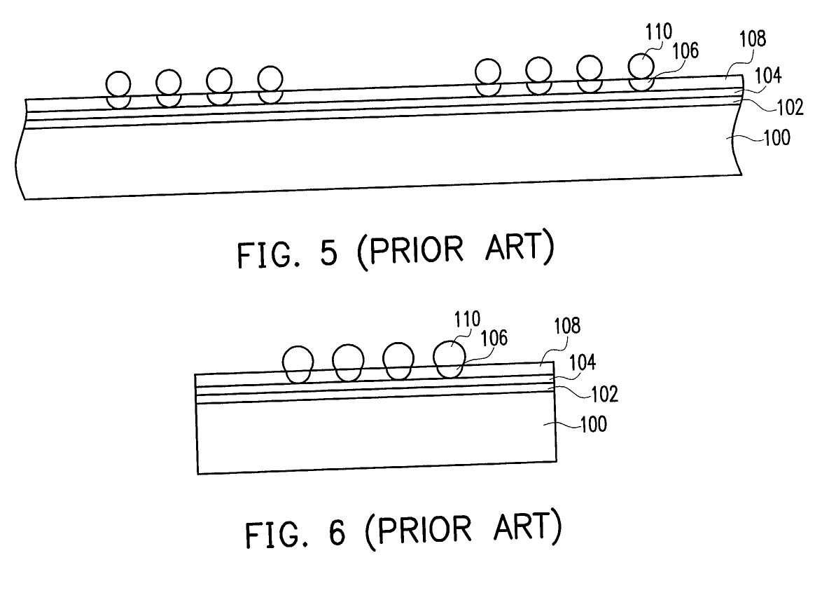

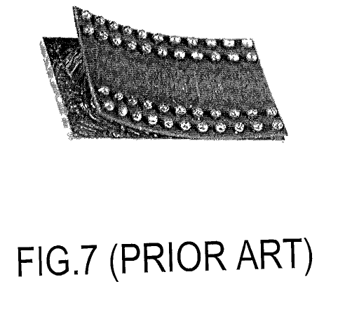

### DESCRIPTION OF THE PREFERRED EMBODIMENTS

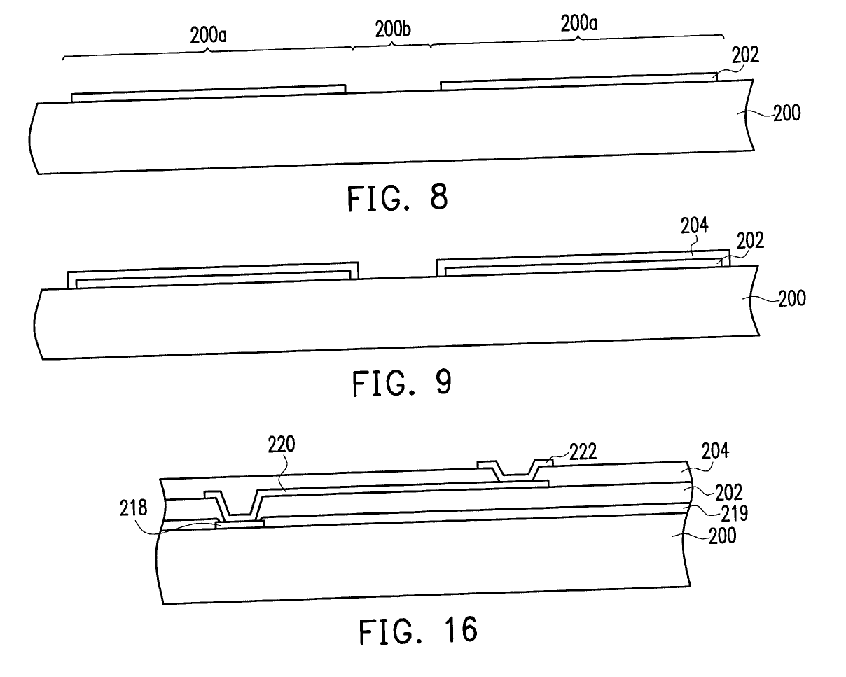

FIGS. 8 to 15 show the fabrication process of a wafer level chip scale package in one embodiment of the present invention. In FIG. 8, a wafer 200 with an active area 200a surrounded by a peripheral area 200b is provided. A first dielectric layer 202 covering only the active area 202a is formed on the wafer 200.

In FIG. 9, a second dielectric layer 204 is formed. The second dielectric layer 204 is allocated on the first dielectric layer 202, and is large enough to encapsulate the first dielectric layer 202 therein. With the first dielectric layer 202 covered within the second dielectric layer 204, the peeling problem between the first dielectric layer 202 and the second dielectric layer 204 caused by the difference in the coefficient of thermal expansion or poor adhesion is avoided.

In FIG. 16, a redistribution layer formed between the first and second dielectric layers 202 and 204 is shown. The wafer 200 has multiple pads 218 and a passivation layer 219 thereon. The pads 218 are electrically connected to the under-ball metallurgies (UBM) 222 of the second dielectric layer 204 via the redistribution layer 220 between the first and second dielectric layers 202 and 204 so to assist the subsequent ball placement process.

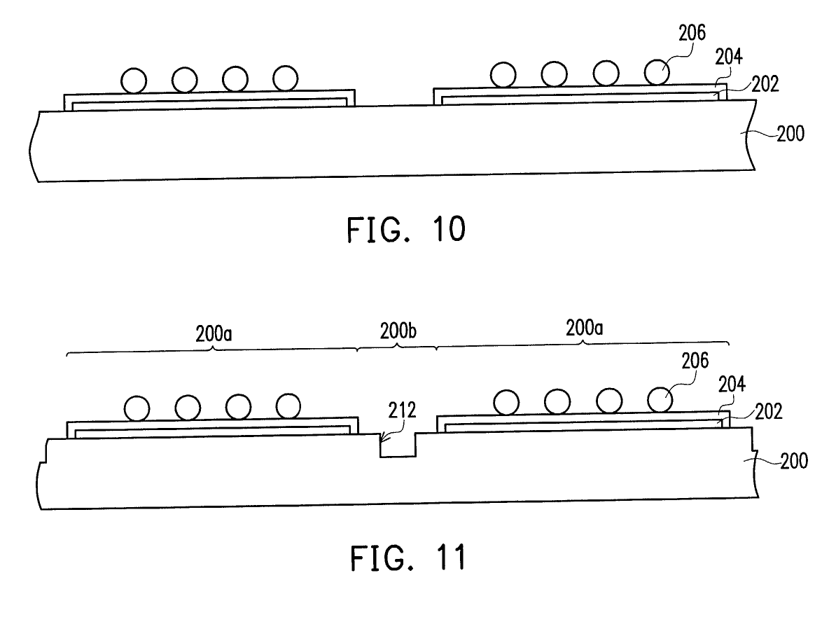

Referring to FIGS. 16 and 10, a first ball placement process is performed after fabricating the first and second dielectric layers 202 and 204. The first solder balls 206 are formed on the under-ball metallurgies 222. A solder back step is performed, so that the first solder balls 206 are mounted to the under-ball metallurgies 222. Before forming the first solder balls 206, a flux or other solder paste may be coated on the under-ball metallurgies 222 to improve the adhesion between the first solder balls 206 and the under-ball metallurgies 222.

In FIG. 11, a pre-cut process is performed to form trenches 212 on the peripheral area 200b of the wafer 200. The depth of the trenches is about ⅓ to ½ of the thickness of the wafer 200. . In addition, the cutting tool used in the pre-cut process has a blade wider than that used in a subsequent singulating process for separating the chips..

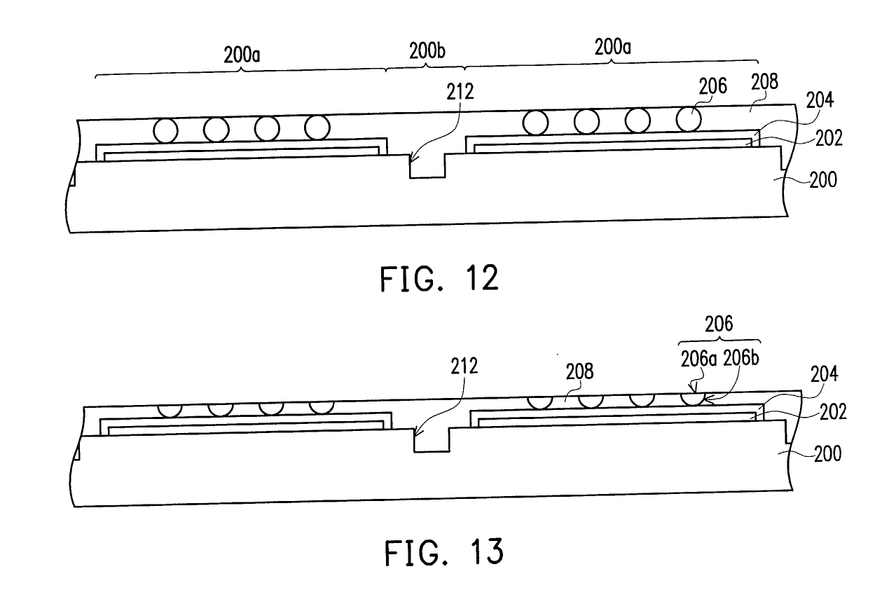

In FIG. 12, a stress buffer layer 208 is formed on the wafer 200 to enclose the first solder balls 206. The stress buffer layer 208 is globally distributed over the active area 200a and the peripheral area 200b of the wafer 200, such that the trenches 212 are filled therewith. The connecting side of the chip is thus completely enclosed thereby. The stair-like junction formed by the trenches 212 can improve the adhesion between the stress buffer layer 208 and the second dielectric layer 204 or between the stress buffer layer 208 and the wafer 200.

In FIG. 13, the stress buffer layer 208 and the first solder balls 206 therein are ground until the height of the first solder balls 206 becomes about 1/4 to 1/2 of the original height thereof. Each of the ground first solder balls 206 has an exposed planar portion 206a and a connecting portion 206b connected to the under-ball metallurgies 222. The connecting portions 206b are still enclosed by the stress buffer layer 208.

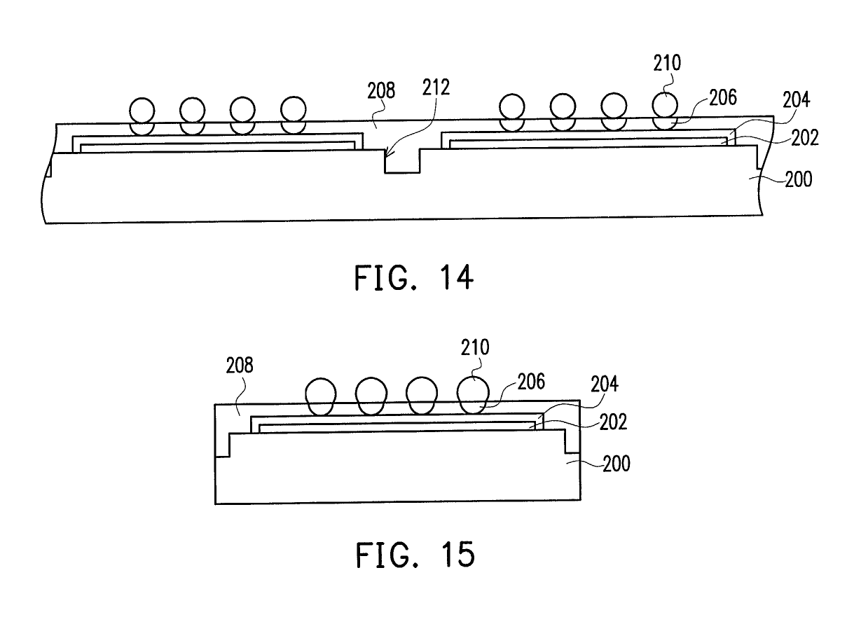

In FIG. 14, a second ball placement process is performed to allocate the second solder balls 210 on the exposed planar portions 206a of the first solder balls 206. Before the second ball placement process, a flux or other solder paste may be coated on the exposed planar portions 206a of the first solder balls 206.

In FIG. 15, a singulation process is performed to the wafer, so that the chips on the wafer are divided into individual chips.. The cutting tool used here has a blade narrower than that used in the pre-cut process, so that the stress buffer layer 208 within the trenches 212 is not completely removed. Being singulated, a stair-like junction is formed between the stress buffer layer 208 and the wafer 200. The stair-like structure prevent the occurrence of the peeling of the stress buffer layer 208. Further, such structure lengthens the path for external moisture to penetrate into the package. The problems caused by moisture penetration are thus resolved.

Accordingly, the above wafer level chip scale package has the following advantages.

1. The peeling problem between the dielectric layers caused by the difference in coefficient of the thermal expansion or poor adhesion thereof is improved.

2. The peeling problem between the stress buffer layer and second dielectric layer or between the stress buffer layer and the wafer caused by the difference in the coefficient of thermal expansion or the poor adhesion thereof is improved.

3. The stair-like structure of the junction lengthens the path for external moisture penetration so that problems caused thereby are resolved.

4. The yield and reliability are enhanced due to the above advantages.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A fabrication method of a wafer level chip scale package, comprising:
providing a wafer having a plurality of chips thereon, wherein each chip has an active area with a plurality of pads thereon, and a passivation layer to protect the wafer with the pads exposed;
forming a plurality of first solder balls over the chips;
performing a first solder back process to mount the first solder balls to the chips;
performing a pre-cut process to form a plurality of trenches between the chips;
forming a stress buffer layer over the wafer to fill the trenches and encapsulate the first solder balls;
grinding the stress buffer layer to a suitable thickness so that a surface portion of the first solder balls and a top surface of the stress buffer layer are exposed;
forming a plurality of second solder balls on the exposed first solder balls;
performing a second solder back process to mount the second solder balls to the first solder balls; and
performing a singulation process to separate the chips.

2. The fabrication method according to claim 1, further comprising the following steps before forming the first solder balls over the chips:
forming a first dielectric layer covering only the active areas of the chips;
forming a second dielectric layer large enough to cover the first dielectric layer; and
forming a plurality of under-ball metallurgies on the second dielectric layer; wherein
the pads are electrically connected to the under-ball metallurgies via a redistribution layer formed between the first dielectric layer and the second dielectric layer.

3. The fabrication method according to claim 2, further comprising a step of coating a flux on the under-ball metallurgies before forming the first solder balls over the chips.

4. The fabrication method according to claim 2, further comprising a step of coating a solder paste on the under-ball metallurgies before forming the first solder balls over the chips.

5. The fabrication method according to claim 1, further comprising the following steps before forming the first solder balls over the chips:
forming a first dielectric layer located on the active areas of the chips; and forming a plurality of under-ball metallurgies on the first dielectric layer;

6. The fabrication method according to claim 5, further comprising a step of coating a flux on the under-ball metallurgies before forming the first solder balls over the chips.

7. The fabrication method according to claim 1, wherein a cutting tool used in the pre-cut process has a blade wider than that used in the singulation process.

8. The fabrication method according to claim 1, wherein the trenches have a depth about ⅓ to about ½ of the thickness of the wafer.

9. The fabrication method according to claim 1, further comprising a step of coating a flux on the exposed first solder balls before forming the second solder balls.

10. A wafer level chip scale package, comprising:
a chip, having an active area and a peripheral area peripheral to the active area, wherein a plurality of pads and a passivation layer with the pads exposed are formed on the active area, and a thickness of the peripheral area is smaller than that of the active area;
at least one dielectric layer located on the active area, wherein the dielectric layer has a redistribution layer therein;
a plurality of under-ball metallurgies, electrically connected to the pads via the redistribution layer;
a plurality of first solder balls formed on and connected to the under-ball metallurgies;
a stress buffer layer, over the chip to cover the first solder balls with portions thereof exposed;
a plurality of second solder balls, on the exposed portions of the first solder balls.

11. The wafer level chip scale package according to claim 10, wherein a thickness difference between the peripheral area and the active area is about ⅓ to about ½ of the thickness of that of the active area.

12. The wafer level chip scale package according to claim 10, wherein a total height of the first solder balls after being ground plus a height of the second solder balls is about 300 microns to 700 microns.

13. The wafer level chip scale package according to claim 10, wherein the dielectric layer further comprises the under-ball metallurgies.

14. The wafer level chip scale package according to claim 10, wherein the dielectric layer further comprises:
a first dielectric layer, located on the active area; and
a second dielectric layer, on the first dielectric layer and the active area to cover the first dielectric layer; wherein
the redistribution layer is formed between the first and the second dielectric layers to electrically connect the pads and the under-ball metallurgies.

15. A wafer level chip scale package, comprising:
a chip, having an active area and a peripheral area around the active area, wherein a plurality of pads and a passivation layer with the pads exposed are formed on the active area, and a thickness of the peripheral area is smaller than that of the active area;
a first dielectric layer, formed on the active area;
a second dielectric layer, formed on and covering the first dielectric layer;
a plurality of under-ball metallurgies on the second dielectric layer;
a plurality of first solder balls formed on and connected to the under-ball metallurgies;
a stress buffer layer, formed over the chip and encapsulated the first solder balls, wherein a surface portion of the first solder balls is exposed after grinding;
a plurality of second solder balls, on the exposed portions of the first solder balls.

16. The wafer level chip scale package according to claim 15, wherein a thickness difference between the peripheral area and the active area is about ⅓ to about ½ of the thickness of the active area.

17. The wafer level chip scale package according to claim 15, wherein a total height of the first solder balls after being ground plus a height of the second solder balls is about 300 microns to 700 microns.
